(19) United States
(12) Patent Application Publication
(10) Pub. No.: US 2020/0227588 A1
(43) Pub. Date: Jul. 16, 2020

(54) RADIATION-EMITTING SEMICONDUCTOR CHIP

(71) Applicant: Osram OLED GmbH, Regensburg (DE)

(72) Inventors: Fabian Kopp, Tanjung Tokong (MY); Attila Molnar, Gelugor, Penang (MY)

(21) Appl. No.: 16/640,063

(22) PCT Filed: Aug. 21, 2018
(86) PCT No.: PCT/EP2018/072492

§ 371 Date: Feb. 19, 2020

(30) Foreign Application Priority Data
Aug. 30, 2017 (DE) 10 2017 119 881.4

(51) Int. Cl. H01L 33/08; H01L 33/38; H01L 33/62

(52) U.S. Cl. CPC H01L 33/08; H01L 33/62; H01L 33/382

(57) ABSTRACT

A radiation-emitting semiconductor chip may include a semiconductor body having a first layer, a second layer, and an active layer therebetween. The active layer may be subdivided into a multiplicity of segments in a plan view of the chip. A separating structure may be formed in the semiconductor body between neighboring segments. The multiplicity of segments may be electrically connected to one another in series and/or in parallel. At least one segment may be assigned a first contact layer having a first contact finger structure and a second contact layer having a second contact finger structure. There may be a direct electrical contact between the first contact layer and the second contact layer in places.

### CROSS-REFERENCE TO RELATED APPLICATIONS

The present application is a national stage entry according to 35 U.S.C. § 371 of PCT application No.: PCT/EP2018/072492 filed on Aug. 21, 2018; which claims priority to Germany application No.: 10 2017 119 881.4, which was filed on Aug. 30, 2017; both of which are incorporated herein by reference in their entirety and for all purposes.

### TECHNICAL FIELD

A radiation-emitting semiconductor chip is disclosed.

### BACKGROUND

For the efficient operation of radiation-emitting semiconductor components, for example light-emitting diode semiconductor chips, efficient current distribution in the lateral direction is desired. To this end, for example, metal contact structures or transparent conductive layers may be used. This, however, may lead to absorption losses so that the efficiency of the semiconductor chip is reduced. Furthermore, such semiconductor chips are often operable only with relatively low voltages.

### SUMMARY

It is an object to provide a radiation-emitting semiconductor chip which is distinguished, in particular, by a high efficiency and low absorption losses even with relatively high applied voltages.

A radiation-emitting semiconductor chip is provided, which includes a semiconductor body. The semiconductor body includes an active region intended to generate radiation. For example, the active region is intended to generate radiation in the ultraviolet, visible or infrared spectral range. The active region is, in particular, arranged between a first semiconductor layer and a second semiconductor layer, the first semiconductor layer and the second semiconductor layer being different to one another at least in places in respect of their conduction type, so that the active region is located in a pn junction. The first semiconductor layer, the second semiconductor layer and the active region may respectively be configured as one layer or as a plurality of layers.

According to at least one embodiment of the radiation-emitting semiconductor chip, the active region is subdivided into a multiplicity of segments in a plan view of the semiconductor chip, a separating structure respectively being formed in the semiconductor body between two neighboring segments. In the lateral direction of the active region, the segments are thus not electrically conductively connected directly to one another. In other words, the segments of the active region are not electrically conductively connected to one another in a plane extending through the active regions. During production of the radiation-emitting semiconductor chip, all the segments of the active region are expediently obtained from a common active layer sequence. The separating structure may furthermore electrically separate one or more semiconductor layers, in particular all the semiconductor layers, of two neighboring segments fully from one another in the vertical direction. For example, the separating structure separates the second semiconductor layer of neighboring segments from one another, the second semiconductor layer being arranged between the active region and a substrate of the semiconductor chip. For example, the separating structure extends through the entire semiconductor body in the vertical direction as far as the substrate of the semiconductor chip.

A lateral direction is intended to mean a direction which extends parallel to a main extent plane of the active region. Correspondingly, a vertical direction extends perpendicularly to the main extent plane of the active region.

According to at least one embodiment of the radiation-emitting semiconductor chip, the multiplicity of segments are electrically connected to one another in series and/or parallel. In particular, all the segments of the semiconductor chip may be electrically connected to one another. For example, at least two segments or even all the segments are electrically connected to one another in series. The greater the number of segments connected in series is, the higher is the voltage which may be externally applied to the radiation-emitting semiconductor chip.

According to at least one embodiment of the radiation-emitting semiconductor chip, at least one segment is assigned a first contact layer having a first contact finger structure for electrical contacting of the first semiconductor layer. In particular, a part of the first contact layer may respectively be arranged on all the segments. The first contact layer includes, for example, a first contact pad for external electrical contacting of the semiconductor chip. The first contact finger structure is intended for lateral distribution of charge carriers, for example holes, which are introduced through the first contact pad during operation of the radiation-emitting semiconductor chip.

According to at least one embodiment of the radiation-emitting semiconductor chip, at least one segment is assigned a second contact layer having a second contact finger structure for electrical contacting of the second semiconductor layer. In particular, a part of the second contact layer may respectively be arranged on all the segments. The second contact layer includes, for example, a second contact pad for external electrical contacting of the semiconductor chip. The second contact finger structure is intended for lateral distribution of charge carriers, for example electrons, which are introduced through the second contact pad during operation of the radiation-emitting semiconductor chip.

There may be a direct electrical contact between the first contact layer and the second contact layer in places, for example in a contact region for series electrical connection of two segments. For example, the first contact layer and the second contact layer adjoin one another directly in the contact region.

According to at least one embodiment of the radiation-emitting semiconductor chip, the first contact finger structure and the second contact finger structure overlap at least in places in a plan view of the semiconductor chip. Regions in which the first contact finger structure and the second contact finger overlap may be used both for the lateral current distribution for the contacting of the first semiconductor layer and for the lateral current distribution for the contacting of the second semiconductor layer. These regions may thus be used both for the lateral distribution of electrons and for the lateral distribution of holes. For example, at least 10%, at least 30% or at least 90% of the first contact finger structure lies inside the second contact finger structure in a plan view of the semiconductor chip. The greater this percentage is, the more area of the semiconductor chip, which because of the second contact finger structure is not usable anyway for the radiation generation, may additionally be used for the charge carrier distribution via the first contact finger structure. Compared with a radiation-emitting semiconductor chip in which the first contact layer and the second contact layer are arranged next to one another without overlap, the active region area covered by the contact layers may be reduced. One of the contact layers, for example the first contact layer, may however also include at least one contact finger which is configured without overlap with the other, for example the second, contact layer. In contrast thereto, the first contact pad and the second contact pad are expediently arranged without overlap with one another, so that both contact pads are accessible for the external electrical contacting.

In particular, the first contact finger structure may include a number of contact fingers which is greater than or equal to the number of contact fingers of the second contact finger structure.

A contact finger structure is generally intended to mean a region of a contact layer which has a relatively small extent at least in a lateral direction in comparison with the contact pad intended for the external electrical contacting.

According to at least one embodiment of the radiation-emitting semiconductor chip, the radiation-emitting semiconductor chip includes a semiconductor body, which includes a first semiconductor layer, a second semiconductor layer and an active region, which is arranged between the first semiconductor layer and the second semiconductor layer and is intended to generate radiation. In a plan view of the semiconductor chip, the active region is subdivided into a multiplicity of segments, a separating structure respectively being formed in the semiconductor body between neighboring segments. The multiplicity of segments are electrically connected to one another in series and/or in parallel. At least one segment is assigned a first contact layer having a first contact finger structure for electrical contacting of the first semiconductor layer and a second contact layer having a second contact finger structure for electrical contacting of the second semiconductor layer, the first contact finger structure and the second contact finger structure overlapping in places in a plan view of the semiconductor chip.

According to at least one embodiment of the radiation-emitting semiconductor chip, the first contact layer and the second contact layer overlap with the separating structure at least between two segments in a plan view of the semiconductor chip. In particular, the first contact layer and the second contact layer may adjoin one another directly in the region of the separating structure. In other words, a contact region between the first contact layer and the second contact layer overlaps with the separating structure.

According to at least one embodiment of the radiation-emitting semiconductor chip, either only the first contact layer or only the second contact layer overlaps with the separating structure at least between two segments in a plan view of the semiconductor chip. For example, the first contact layer and the second contact layer overlap only in a region which is laterally separated from the separating structure. In other words, a contact region between the first contact layer and the second contact layer and the separating structure are arranged in plan view next to one another without overlap.

According to at least one embodiment of the radiation-emitting semiconductor chip, the separating structure is formed by a separating trench, which extends into the semiconductor body, in particular fully through the semiconductor body, in the vertical direction. In the region of the separating structure, material of the semiconductor body is thus removed at least in places or fully.

According to at least one embodiment of the radiation-emitting semiconductor chip, the separating trench is filled to at least 30% of its vertical extent with an electrically insulating filler material, in particular to at least 70% or to at least 90%. Even with a relatively large vertical extent of the separating trench, it is thus straightforwardly ensured that layers to be placed over the trench in the lateral direction can be formed reliably and, in particular, it is not necessary to mold over any edges with large height differences. For example, the electrically insulating filler material extends in regions in the vertical direction between the substrate and the first contact layer and/or between the substrate and the second contact layer. For example, the electrically insulating filler material directly adjoins the substrate.

According to at least one embodiment of the radiation-emitting semiconductor chip, a side face of the separating trench is inclined at an angle of at most 70° with respect to a main extent plane of the active region, in particular at an angle of at most 65° or at most 60°. In the case of a coating of the side face, for instance with the first contact layer and/or the second contact layer, the thickness of the applied coating on the side face is proportional to the cosine of the angle. By a shallow angle of the side face, a sufficient current-carrying capacity of an electrically conductive coating may therefore be achieved in a simplified way, in particular with a consistent lateral extent of the coating.

According to at least one embodiment of the radiation-emitting semiconductor chip, the separating structure is formed by means of a region of the semiconductor body in which an electrical conductivity is modified, in particular reduced, in comparison with a laterally adjacent material of the semiconductor body. In the region of the separating structure, the semiconductor material of the semiconductor body is thus not removed, but merely modified in respect of its conductivity in such a way that no direct lateral current flow, or no significant direct lateral current flow, takes place between neighboring segments. Such a region, which may in particular be electrically insulating, may for example be achieved by ion implantation.

According to at least one embodiment of the radiation-emitting semiconductor chip, the semiconductor chip includes a current distribution layer. The current distribution layer is electrically conductively connected to the first contact layer. For example, the current distribution layer directly adjoins the first contact layer. For example, the first contact layer is arranged fully inside the current distribution layer in a plan view of the semiconductor chip.

According to at least one embodiment of the radiation-emitting semiconductor chip, the semiconductor chip includes a connecting layer. The connecting layer is electrically conductively connected to the first contact layer, for example by means of the current distribution layer. In particular, the connecting layer directly adjoins the semiconductor body, in particular the first semiconductor layer. For example, the connecting layer does not directly adjoin the first contact layer at any position.

In particular, the current distribution layer is electrically conductively connected to the first semiconductor layer by means of the connecting layer.

According to at least one embodiment of the radiation-emitting semiconductor chip, the first contact finger structure is electrically conductively connected to the current distribution layer, and includes at least one subregion in which the current distribution layer is not directly adjacent. The subregion thus represents a region in which no direct charge carrier injection takes place from the first contact finger structure into the current distribution layer. The lateral charge carrier injection is thus deliberately controllable.

According to at least one embodiment of the radiation-emitting semiconductor chip, the semiconductor chip includes an insulation layer. The insulation layer contains, for example, a dielectric material. The dielectric material is an electrically weakly conducting or nonconductive nonmetallic material, the charge carriers of which are in general—i.e. for example with the conventional operating currents—not freely mobile. The insulation layer contains, for example, at least one of the following materials: silicon nitride, silicon dioxide, silicon oxynitride, aluminum oxide, titanium oxide, tantalum oxide, niobium oxide.

The insulation layer covers for example at least 30%, for instance at least 50%, at least 70% or at least 90% of the total base area of the semiconductor chip in plan view. For example, the insulation layer covers at most 99% of the total base area of the semiconductor chip in plan view.

For example, the insulation layer is arranged between the connecting layer and the current distribution layer in places, in particular as seen in the vertical direction. By means of the insulation layer, a direct vertical current path between the connecting layer and the current distribution layer is thus prevented at least in places.

As an alternative or in addition, the insulation layer may be arranged between the first contact layer and the second contact layer in the vertical direction.

According to at least one embodiment of the radiation-emitting semiconductor chip, the insulation layer covers the connecting layer to at least 30% of the area of the connecting layer. For example, the insulation layer covers the connecting layer to at least 50%, to at least 70% or to at least 90%. The insulation layer may thus cover the connecting layer over a large area. For example, the insulation layer covers the connecting layer to at most 95% or to at most 99%.

According to at least one embodiment of the radiation-emitting semiconductor chip, the insulation layer includes at least one opening. For example, the connecting layer and the current distribution layer adjoin one another in the opening. In other words, the connecting layer and the current distribution layer are electrically connected to one another in the region of the opening. In particular, the connecting layer and the current distribution layer adjoin one another only in the at least one opening. For example, the opening is surrounded along its entire circumference by material of the insulation layer. For example, the opening is filled with material of the current distribution layer at least in regions.

According to at least one embodiment of the radiation-emitting semiconductor chip, the insulation layer includes a multiplicity of openings. By means of the position of the openings, during production of the semiconductor chip it is possible to adjust positions at which the current distribution layer adjoins the connecting layer. For example, the openings are configured in respect of their distribution density and/or their size in such a way that current introduction which is uniform in the lateral direction into the semiconductor chip is promoted. A distance between two neighboring openings is for example between 5 μm inclusive and 60 μm inclusive, for instance between 20 μm inclusive and 50 μm inclusive. A diameter of the openings is in particular between 0.5 μm inclusive and 20 μm inclusive, for example between 2 μm inclusive and 6 μm inclusive. In the case of an opening which is not round, the diameter is intended to mean the longest lateral extent. The openings may also differ from one another in respect of their shape and/or their size. For example, one or more openings which are larger than openings in the central region of the semiconductor chip may also be provided at the edge of the semiconductor chip

According to at least one embodiment of the radiation-emitting semiconductor chip, the insulation layer is configured as a filter layer, which mostly transmits radiation incident within a first angle range and mostly reflects radiation incident within a second angle range. “Mostly” means, in particular, that at least 60% of the radiation is transmitted or reflected, respectively.

In particular, the angles of the first angle range in relation to the vertical direction are less than the angles of the second angle range. Radiation which is incident on the insulation layer at relatively steep angles is thus mostly transmitted, while relatively shallowly incident radiation is mostly reflected. Radiation components which could not be coupled out from the semiconductor chip anyway because of a relatively shallow profile are thus already stopped at the insulation layer. Radiation absorption losses in the layers downstream of the insulation layer, for example in the current distribution layer, may thus be reduced.

For example, the boundary between the first angle range and the second angle range is determined by the critical angle of total internal reflection, which may be derived from the refractive index of the semiconductor body and the refractive index of the surrounding medium. The first angle range in this case includes angles that are less than this boundary. The second angle range, on the other hand, includes angles that are greater than this boundary.

The insulation layer, configured in particular as a filter layer, may consist of a single layer. This means, in particular, that the insulation layer is configured homogeneously and, for example, is formed from a single dielectric material. The dielectric material advantageously has an adapted refractive index, “adapted” meaning that the refractive index of the dielectric material is greater than or equal to the refractive index of a medium surrounding the insulation layer. With respect to the semiconductor body, the surrounding medium is arranged downstream of the insulation layer. The surrounding medium includes elements which enclose the semiconductor body and, in particular, have a protective function. For example, the semiconductor body may include a passivation layer as a surrounding medium and/or be arranged in an encapsulation.

In an alternative configuration, the insulation layer, configured in particular as a filter layer, is configured as a plurality of layers, and includes at least two sublayers that differ from one another in their refractive index. In a non-limiting embodiment, the filter layer includes a layer sequence of alternating sublayers with a higher refractive index and a lower refractive index. In particular, the sublayers with a higher refractive index have a smaller thickness than the sublayers with a lower refractive index.

In a non-limiting embodiment, the insulation layer, configured in particular as a filter layer, has a thickness of between 400 nm inclusive and 800 nm inclusive. When dimensioning the thickness of the insulation layer, it is necessary to ensure on the one hand that the production outlay which is greater in the case of a multilayer structure of the insulation layer than in the case of a single-layer structure, remains within limits and, on the other hand, optionally the desired filter characteristic, which in the present case can be produced better by a multilayer structure than by a single-layer structure, is nevertheless achieved. With a thickness of between 400 nm inclusive and 800 nm inclusive, a suitable compromise may be reached between production outlay and filter characteristic.

According to at least one embodiment of the radiation-emitting semiconductor chip, the insulation layer adjoins the connecting layer and the current distribution layer. Apart from the insulation layer, there are therefore no further layers in the vertical direction between the connecting layer and the current distribution layer, at least in places. In other words, the insulation layer is at least in places the only layer that is arranged between the connecting layer and the current distribution layer.

According to at least one embodiment of the radiation-emitting semiconductor chip, the connecting layer has a smaller thickness than the current distribution layer. For example, the current distribution layer is at least two times as thick as the connecting layer. For example, a thickness of the connecting layer is between 3 nm inclusive and 30 nm inclusive, for instance between 5 nm inclusive and 25 nm inclusive. A thickness of the current distribution layer is for example between 30 nm inclusive and 200 nm inclusive, for instance between 50 nm inclusive and 150 nm inclusive. In particular because of the greater thickness, the current distribution layer is distinguished by a higher transverse conductivity than the connecting layer. The connecting layer, on the other hand, also has lower absorption losses for the radiation passing through the connecting layer because of the smaller thickness.

Radiation absorption losses in the current distribution layer may be reduced by means of the insulation layer, acting in particular as a filter layer. In other words, by means of the combination of a connecting layer and a current distribution layer, and in particular an insulation layer arranged between them in the vertical direction in regions, a high transverse conductivity is achieved together with low absorption losses.

According to at least one embodiment of the radiation-emitting semiconductor chip, at least 50% of the total area of the second contact finger structure overlaps with the first contact finger structure. In other words, at least half of the area covered by the second contact finger structure is also used for the current distribution by means of the first contact finger structure.

According to at least one embodiment of the radiation-emitting semiconductor chip, the semiconductor body includes at least one recess, which extends from the radiation exit surface through the active region. In particular, the second contact layer is electrically conductively connected to the semiconductor body in the recess. For example, the second contact layer directly adjoins the semiconductor body, in particular the second semiconductor layer. For example, material of the insulation layer and/or material of the current distribution layer is arranged at least in places in the recess.

The recess may, however, also be fully filled with material of the second contact layer.

According to at least one embodiment of the radiation-emitting semiconductor chip, at no position of the semiconductor chip is there a direct vertical current path between the first contact layer and the semiconductor body. Charge carrier injection from the first contact layer into the semiconductor body thus does not take place directly below the first contact layer, but at a distance therefrom in the lateral direction. In this way, the proportion of radiation that is generated directly below the first contact layer in the active region, and is hindered from radiation exit by the first contact layer, is reduced.

According to at least one embodiment of the radiation-emitting semiconductor chip, the connecting layer and/or the current distribution layer contains a TCO material.

Transparent electrically conductive oxides (transparent conductive oxides, TCO) are transparent conductive materials, generally metal oxides, for example zinc oxide, tin oxide, cadmium oxide, titanium oxide, indium oxide, or indium tin oxide (ITO). Besides binary metal-oxygen compounds, for example ZnO, SnO₂ or In₂O₃, ternary metal-oxygen compounds, for example Zn₂SnO₄, CdSnO₃, ZnSnO₃, MgIn₂O₄, GaInO₃, Zn₂In₂O₅ or In₄Sn₃O₁₂, or mixtures of different transparent conductive oxides, also belong to the group of TCOs. Furthermore, the TCOs do not necessarily correspond to a stoichiometric composition and may also be p- or n-doped.

The connecting layer and the current distribution layer may be formed from the same material. As an alternative, the connecting layer and the current distribution layer may also have different material compositions to one another. For example, the contact layer may be selected with a view to a good contact resistance with the semiconductor body and/or the current distribution layer may be selected with a view to a high transmission for radiation generated in the active region.

According to at least one embodiment of the radiation-emitting semiconductor chip, the second contact layer includes a mirror layer. For example, silver, aluminum or rhodium are suitable for the mirror layer. With silver, particularly high reflectivities in the visible spectral range may be achieved. For example, the mirror layer has a thickness of between 300 nm inclusive and 2 μm inclusive.

According to at least one embodiment of the radiation-emitting semiconductor chip, the second contact layer includes a contacting layer. The contacting layer is intended to establish a good ohmic contact with the semiconductor body, in particular with the second semiconductor layer. For example, the contacting layer has a thickness of between 3 nm inclusive and 100 nm inclusive. In particular, the thickness of the contacting layer is at most 50 nm, at most 20 nm or at most 5 nm. The contacting layer is, in particular, arranged between the mirror layer and the second semiconductor layer. Thus, even a material that would form a relatively poor contact with the semiconductor body, for example silver with n-conductive nitride compound semiconductor material, is suitable for the mirror layer. For example, the contacting layer contains a TCO material, for instance ITO or ZnO. In particular with a TCO material for the contacting layer and silver for the mirror layer, it is possible to produce a contact layer that is distinguished by a high reflectivity and at the same time a good electrical contact with the second semiconductor layer. As an alternative, the contacting layer may also contain a metal, for instance Ti or Cr.

According to at least one embodiment of the radiation-emitting semiconductor chip, the second contact layer includes a barrier layer. In particular, the mirror layer is arranged between the contacting layer and the barrier layer. For example, a metal, for instance Ti, Pt, Cu, Rh, Ni, W or Au, or a TCO material, for instance ITO or ZnO, is suitable as a barrier layer. For example, the barrier layer has a thickness of between 30 nm inclusive and 400 nm inclusive. The mirror layer may be encapsulated by means of the barrier layer. For the mirror layer, even a material for which the risk of migration exists, for instance due to moisture, is therefore suitable.

The aforementioned materials and/or at least one or even all the layers may also be used for the first contact layer.

With the described radiation-emitting semiconductor chip, the following effects may be achieved in particular.

By means of the segmentation of the active region, an increased flexibility can be achieved in respect of operating current and/or operating voltage. By a series connection, the operating voltage that can be externally applied is increased, in particular proportionally to the number of segments connected in series. By a parallel connection, the operating current of the semiconductor chip can be increased overall without increasing the operating current through a segment. By a combination of series connection and parallel connection, the two effects may be combined. For example, the segments may be arranged in two or more lines, the lines being connected in parallel with one another and the segments of a line respectively being connected in series with one another.

The regions in which a metal layer, for instance the first contact layer or the second contact layer, directly adjoin the semiconductor chip, are reduced. The brightness of the radiation-emitting semiconductor chip is therefore increased for the same operating current.

By means of the insulation layer, absorption losses are reduced, particularly in the current distribution layer. Even when using a relatively thick current distribution layer with a view to a high transverse conductivity, absorption losses are reduced by means of the insulation layer. In particular, the insulation layer may fulfill the function of an angle-selective filter layer.

The regions in which the greatest current density occurs during operation of the semiconductor chip can be adjusted by means of the at least one opening of the insulation layer. In particular, these regions may be laterally separated from the first contact layer. For example, the regions in which the greatest current density occurs may also be laterally separated from the first contact finger structure.

As a consequence, the amount of light generated in the active region is increased and the efficiency loss with high operating currents (also referred to as droop) is reduced. A better current density distribution and, in association therewith, a homogeneous light distribution, on the radiation exit surface of the semiconductor chip also increase the efficiency of a downstream radiation conversion material, so that the brightness of a component having such a radiation-emitting semiconductor chip is increased further.

The second contact layer itself may be distinguished by particularly low absorption losses, in particular through a multilayer structure with a contacting layer and a mirror layer. Migration effects may be suppressed by means of the barrier layer, so that the freedom in the selection of the material for the mirror layer is increased.

### BRIEF DESCRIPTION OF THE DRAWINGS

Further advantageous embodiments and developments of the component emerge from the exemplary embodiments described below in conjunction with the figures.

FIGS. 1A, 1B and 1C show an embodiment of a radiation-emitting semiconductor chip in a schematic plan view (FIG. 1A), in a schematic side view along the line BB′ shown in FIG. 1A (FIG. 1B) and in a schematic sectional view along the line shown CC′ in FIG. 1A (FIG. 1C);

FIGS. 2, 3, 4, 5 and 6 respectively show an embodiment of a radiation-emitting semiconductor chip in a schematic sectional view; and

FIG. 7 shows an embodiment of a radiation-emitting semiconductor chip in a schematic plan view.

Elements which are the same or of the same type, or which have the same effect, are provided with the same references in the figures.

The figures are respectively schematic representations and therefore not necessarily true to scale. Rather, relatively small elements, and in particular layer thicknesses, may be represented exaggeratedly large for illustration.

### DETAILED DESCRIPTION

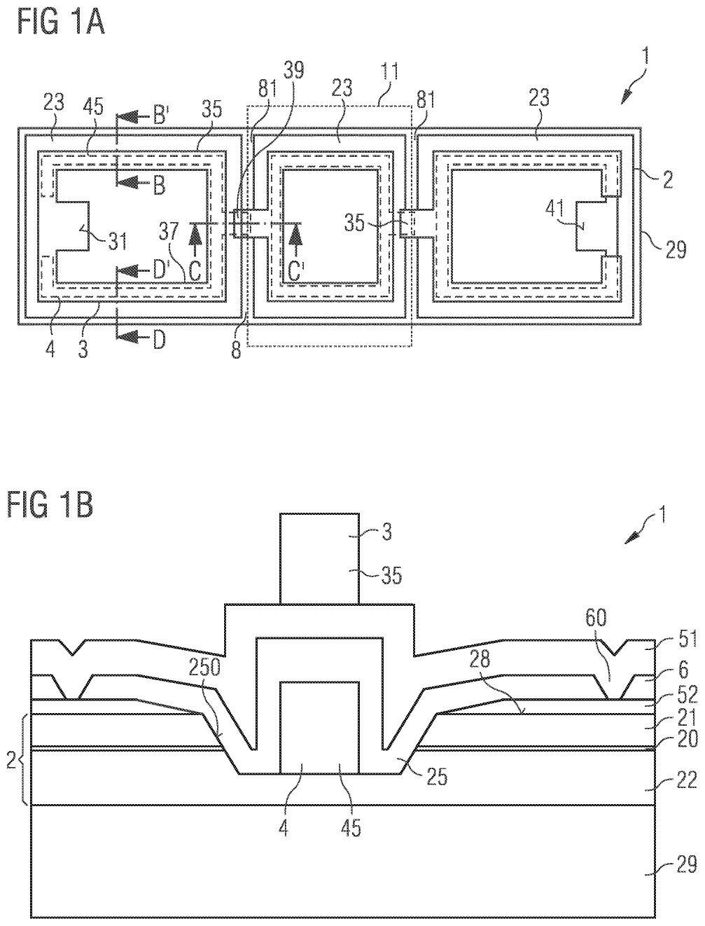

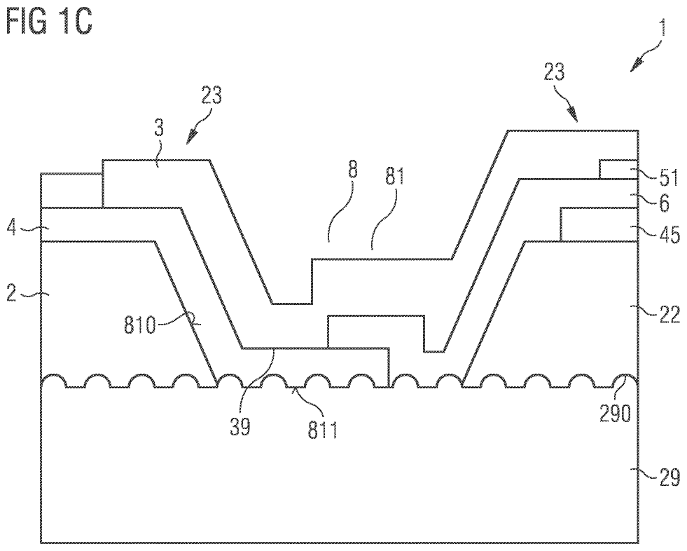

An embodiment of a radiation-emitting semiconductor chip 1 is shown in a plan view in FIG. 1A, while FIGS. 1B and 1C represent in each case sectional views along the lines BB′ and CC′, respectively.

The radiation-emitting semiconductor chip 1 includes a semiconductor body 2 with a semiconductor layer sequence. The semiconductor body 2 includes, in particular, an active region 20 intended to generate radiation, which is arranged between a first semiconductor layer 21 of a first conduction type (for example p-conductive) and a second semiconductor layer 22 of a second conduction type different to the first conduction type (example n-conductive). The semiconductor body 2, in particular the active region 20, is based on a III-V compound semiconductor material, in particular on a nitride compound semiconductor material.

In the present context, “based on nitride compound semiconductor material” means that at least one layer of the semiconductor regions includes a III-V nitride compound semiconductor material, such as AlₙGaₘIn₁₋ₙ₋ₘN, where 0≤n≤1, 0≤m≤1 and n+m≤1. In this case, this material need not necessarily have a mathematically exact composition according to the formula above. Rather, it may include one or more dopants as well as additional constituents that do not substantially alter the characteristic physical properties of the AlₙGaₘIn₁₋ₙ₋ₘN material. For the sake of simplicity, however, the formula above only contains the essential constituents of the crystal lattice (Al, Ga, In, N), even though these may be partially replaced with small amounts of other substances.

The semiconductor body 2 is arranged on a substrate 29. In particular, the substrate is a growth substrate for the epitaxial deposition of the semiconductor layer sequence of the semiconductor body. For a semiconductor body based on nitride compound semiconductor material, for example sapphire, silicon carbide, silicon or gallium nitride are suitable as a growth substrate.

A first contact layer 3 and a second contact layer 4 are arranged on a radiation exit surface 28, facing away from the substrate 29, of the semiconductor body 2. The first contact layer 3 includes a first contact pad 31 for the external electrical contacting of the first semiconductor layer 21. The second contact layer 4 includes a second contact pad 41 intended for the external electrical contacting of the second semiconductor layer.

The first contact layer 3 furthermore includes a first contact finger structure 35, which is connected to the first contact pad 31. Correspondingly, the second contact layer 4 includes a second contact finger structure 45, which is electrically conductively connected to the second contact pad 41.

The active region 20 is subdivided into a multiplicity of segments 23, in FIG. 1A by way of example into three segments. The segments 23 are respectively electrically connected to one another in series. In relation to a segment having an operating voltage of 3 V, the operating voltage which can be externally applied between the first contact pad 31 and the second contact pad 41 is increased by the factor n, where n is the number of segments 23 connected in series, i.e. in the example shown to 3*3 V=9 V.

More segments 23 may, however, also be used. This is illustrated in FIG. 1A with the aid of a unit cell 11. The unit cell respectively includes on opposite sides the corresponding contact layers for the electrical contacting with the neighboring segments, and in principle may be positioned an arbitrary number of times between the two outer segments 23.

All the segments of the semiconductor chip 1 can be externally contacted via precisely one first contact pad 31 and precisely one second contact pad of the semiconductor chip.

The segments 23 may, in particular, be configured in such a way that the active regions have the same, or substantially the same, active area 20 in a plan view of the semiconductor chip, for instance with a deviation of at most 20% or at most 10%. To this end, subregions of the semiconductor body 2 that form a segment 23 having a contact pad may be larger than subregions that form a segment without a contact pad. Thus, it is straightforwardly possible to achieve the situation that in the segments 23, through which the same current respectively flows because of the series connection, the same or at least substantially the same average current densities occur.

A separating structure 8 is respectively arranged between neighboring segments. In FIG. 1C, the separating structure is formed by means of a separating trench 81. The separating trench cuts fully through the semiconductor layer sequence of the semiconductor body 2 in the vertical direction. A bottom surface 811 of the separating trench is formed by the substrate 29. In particular, the substrate 29 is electrically insulating, so that the segments are not electrically conductively connected to one another by means of the substrate.

The first contact layer 3 of a segment 23 and the second contact layer 4 a neighboring segment 23 are electrically conductively connected to one another in a contact region 39 and directly adjoin one another there. This leads to a series electrical connection of these segments.

The first contact layer 3 of a segment 23 and the second contact layer 4 a neighboring segment 23 furthermore overlap with the separating structure 8. The two contact layers cover the bottom surface 811 of the separating trench 81 in places.

A side face 810 of the separating trench 81 is inclined at an angle of at most 70° with respect to a main extent plane of the active region, such as at most 65° or at most 60°. The shallower the angle is, the thicker is the layer thickness, measured perpendicularly to the side face 810, of the layers applied onto the side face, in particular the first contact layer 3 and the second contact layer 4. A sufficiently high current-carrying capacity may thus be achieved with a relatively small lateral extent of the contact layers in the region of the separating trench 81. In other words, the cross section of the first contact layer 3 and/or of the second contact layer 4 may be kept almost constant in the region of the separating trench.

In the embodiment shown in FIG. 1A, the segments 23 are respectively assigned a first contact finger structure 35 and a second contact finger structure 45. These respectively include two contact fingers, which together extend around the respective segment in the manner of a frame. In contrast thereto, however, other structures may also be envisioned, for example contact fingers extending in a curved fashion in places, a comb-like configuration or a configuration of the contact finger structures similar to the venation of a leaf. The number of contact fingers may also be varied within wide limits. The numbers of contact fingers of the first contact finger structure 35 and of the second contact finger structure 45 may also be different to one another. For example, the number of contact fingers of the first contact finger structure is greater than the number of contact fingers of the second contact finger structure.

The first contact finger structure 35 and the second contact finger structure 45 overlap in a plan view of the radiation-emitting semiconductor chip 1. In this way, regions of the semiconductor chip in which the active region 20 is removed anyway for the formation of the second contact finger structure 45 may also be used for the current distribution for the electrical contacting of the first semiconductor layer 21.

In contrast to the embodiment described, the first contact finger structure 35 and the second contact finger structure 45 may also overlap to a smaller percentage. For example, the first contact finger structure 35 may include at least one contact finger which, at least over half of its main extent axis, does not overlap with the second contact finger structure 45.

The second contact layer 4, in particular the second contact finger structure 45, adjoins the second semiconductor layer 22 in a recess 25 of the semiconductor body. By means of the recess, the second semiconductor layer 22 covered by the first semiconductor layer 21 is thus exposed in places for contacting with the second contact layer 4.

An insulation layer 6 is arranged between the first contact layer 3 and the second contact layer 4 as seen in the vertical direction. The insulation layer 6 covers the radiation exit surface 28 of the semiconductor body 2 in regions. In the embodiment shown, the insulation layer 6 furthermore also covers the side faces 250 of the recesses 25.

The semiconductor chip 1 furthermore includes a current distribution layer 51, which is electrically conductively connected to the first contact layer 3. Furthermore, the radiation-emitting semiconductor chip 1 includes a connecting layer 52. The connecting layer 52 is electrically conductively connected to the first contact layer by means of the current distribution layer 51. The insulation layer 6 is arranged in places between the current distribution layer 51 and the connecting layer 52, in particular as seen in the vertical direction.

The insulation layer 6 includes a multiplicity of openings 60, in which the current distribution layer 51 and the connecting layer 52 adjoin one another. During operation of the radiation-emitting semiconductor chip, the current density introduced into the semiconductor chip is greatest in a region vertically below the openings 60. By means of the openings in the insulation layer 6, it is thus possible to define the regions in which the current density is greatest in the segments 23. Without an insulation layer between the current distribution layer 51 and the connecting layer 52, on the other hand, the current density would be greatest in the region around the first contact layer 3. In lateral regions which are further away from the contact layer 3, on the other hand, only a relatively small charge carrier injection would take place.

The openings 60 are expediently arranged in the lateral direction in such a way that a maximally homogeneous current density distribution is respectively obtained in the segments 23 in the lateral direction. In particular, the arrangement of the openings on the radiation exit surface 28 is also selected, on the basis of the respective material parameters of the current distribution layer 51 and of the connecting layer 52, in such a way that a maximally homogeneous current density distribution is formed.

For example, edge regions of the radiation exit surface 28 may be provided with more openings than central regions of the radiation exit surface. The spacings distances between the openings may be between 20 μm inclusive and 50 μm inclusive. A suitable diameter of the openings is, in particular, between 1 μm inclusive and 15 μm inclusive, for instance between 2 μm inclusive and 6 μm inclusive.

Despite the openings 60, the insulation layer 6 may cover the connecting layer over a large area, for instance to at least 30%, to at least 50% or to at least 70% of the area of the connecting layer in a plan view of the semiconductor chip. For example, the insulation layer covers the connecting layer 52 to at most 90% or to at most 95%.

The connecting layer 52 has a smaller thickness than the current distribution layer 51. In contrast to the current distribution layer 51, the connecting layer 52 need not have a high transverse conductivity. By a relatively small thickness of the connecting layer 52, absorption losses in the connecting layer may be reduced.

As seen from the active region 20, the insulation layer 6 is arranged before the current distribution layer 51 at least in places. The insulation layer 6 may, in particular, fulfill the function of a filter layer, the filter layer having a higher reflectivity for radiation that travels at relatively large angles with respect to the normal to the main extent plane of the active region 20 than for radiation which is incident at a relatively small angle with respect to the normal. In this way, radiation components which cannot emerge from the semiconductor chip 1 anyway because of total internal reflection may already be reflected substantially without loss at the insulation layer 6. Absorption losses in the current distribution layer 51 may thus be reduced. The insulation layer may for example cover at least 50%, for instance at least 70% or at least 90% of the total base area of the semiconductor chip in a plan view. Absorption losses may thus be avoided particularly efficiently by means of the insulation layer 6.

In particular, for radiation in a first angle range, the transmission may be increased in comparison with a conventional semiconductor chip. In this case, the first angle range denotes angles α with 0°≤α≤αₜₒₜ, where αₜₒₜ indicates the critical angle of total internal reflection. At angles α which are greater than the critical angle αₜₒₜ, i.e. in a second angle range with αₜₒₜ<α≤90°, the absorption in the described semiconductor chip is reduced significantly in comparison with a conventional semiconductor chip. The first angle range represents a conical region having a principal axis parallel to the vertical direction. The critical angle αₜₒₜ of total internal reflection is determined by the refractive index of the semiconductor body 2 and the refractive index of the surrounding medium, a semiconductor body 2 formed from GaN with a refractive index n=2.5 and a surrounding material with a refractive index n=1.55 giving a critical angle αₜₒₜ=arcsin(1.55/2.5)=38.3°.

A particularly efficient filter effect may be obtained by a multilayer configuration of the insulation layer with an alternating arrangement of layers with lower and higher refractive index. For simplified representation, the multilayer configuration of the insulation layer is not explicitly shown in FIG. 1B. Even with a single-layer insulation layer, however, a filter effect may already be achieved.

On the side facing away from the substrate 29, the radiation-emitting semiconductor chip 1 may be sealed in regions by a passivation layer (not explicitly shown in the figures for simplified representation). The passivation layer is used, in particular, to protect the semiconductor body against external stresses such as moisture, dust or mechanical stress.

The current distribution layer 51 and the connecting layer 52 may respectively include the same material or different materials to one another. In a non-limiting embodiment, the current distribution layer and the connecting layer contain a TCO material, for example ITO.

The first contact layer 3 and the second contact layer 4, or at least a sublayer thereof, may respectively be made of metal. External electrical contacting of the semiconductor chip 1 is thereby simplified.

The second contact layer 4 may, in particular, be configured as a plurality of layers. This is not represented in the figures for simplified representation. The second contact layer includes for example a contacting layer, a mirror layer and a barrier layer, the mirror layer being arranged between the contacting layer and the barrier layer.

For example, silver or aluminum are suitable for the mirror layer. With silver, particularly high reflectivities in the visible spectral range may be achieved. For example, the mirror layer has a thickness of between 300 nm inclusive and 2 μm inclusive.

By means of the contacting layer, a good ohmic contact may be formed with the semiconductor body, in particular even when using a material for the mirror layer that would form a relatively poor contact with the semiconductor body, for example silver with n-conductive nitride compound semiconductor material. For example, the contacting layer has a thickness of between 3 nm inclusive and 100 nm inclusive. The contacting layer is, in particular, arranged between the mirror layer and the second semiconductor layer. For example, the contacting layer contains a TCO material, for instance ITO or ZnO. In particular with a TCO material for the contacting layer and silver for the mirror layer, the second contact layer may be distinguished by a high reflectivity and at the same time a good electrical contact with the second semiconductor layer.

For example, a metal, for instance Ti, Pt, Cu, or Au, or a TCO material, for instance ITO or ZnO, is suitable for the barrier layer. For example, the barrier layer has a thickness of between 30 nm inclusive and 400 nm inclusive. The mirror layer may be encapsulated by means of the barrier layer. For the mirror layer, even a material for which the risk of migration exists, for instance due to moisture, in particular silver, is therefore suitable.

The first contact layer 3 may also be configured as a plurality of layers and include at least one of the materials described in connection with the second contact layer.

The substrate 29, for example a sapphire substrate, may include a structuring 290 shown in FIG. 1C, in particular on the side facing toward the semiconductor body 2. For example, the substrate has a concave-convex topology. In this way, the output coupling efficiency may be increased further. Nevertheless, a substrate that includes silicon carbide, silicon or gallium nitride, or consists of such a material, may also be used.

Further configurations of radiation-emitting semiconductor chips having overlapping contact finger structures are described in German Patent Application DE 10 2016 112 587.3, the entire disclosure content of which is explicitly incorporated into the present application by reference.

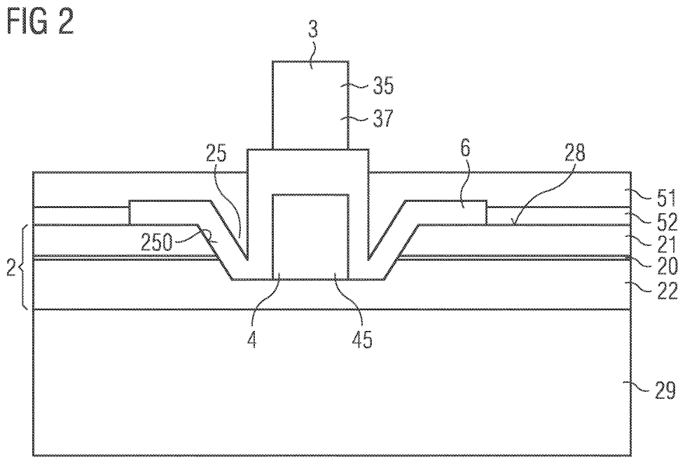

FIG. 2 shows a further embodiment of a radiation-emitting semiconductor chip, the figure representing a section along the line DD′ of FIG. 1A. In contrast to the section represented in FIG. 1B, the first contact finger structure 35 includes a subregion 37 in which the current distribution layer 51 does not directly adjoin the first contact finger structure 35. In this subregion of the first contact finger structure, no direct current introduction into the current distribution layer 51 thus takes place. The first contact finger structure 35 thus includes subregions in which the current distribution layer 51 adjoins the first contact finger structure (FIG. 1B) and subregions in which the current distribution layer 51 does not directly adjoin the first contact finger structure 35 (FIG. 2).

By means of the arrangement of the subregions 37, it is possible to adjust regions of the radiation-emitting semiconductor chip at which locally reduced injection of charge carriers takes place.

Furthermore, in contrast to FIG. 1B, the insulation layer 6 is configured in such a way that the current distribution layer 51 and the connecting layer 52 adjoin one another over a large area. Such a configuration may also be used in the section shown in FIG. 1B. The insulation layer 6 is thus used essentially for electrical insulation between the first contact finger structure 35 and the second contact finger structure 45, as well as for electrical insulation of the current distribution layer 51 from the active region 20 and the second semiconductor layer 22 in the region of the side faces 250 of the recess 25.

Furthermore, the first semiconductor layer 21 is covered by the insulation layer 6 in a region adjacent to the side face 250 of the recess 25. Excessively strong charge carrier injection, in comparison with other lateral regions, directly in the region of the first contact finger structure 35 and of the second contact finger structure 45 can thus be avoided. A controlled lateral current distribution by means of openings in the insulation layer is not, however, carried out, in contrast to the embodiment described in connection with FIG. 1B.

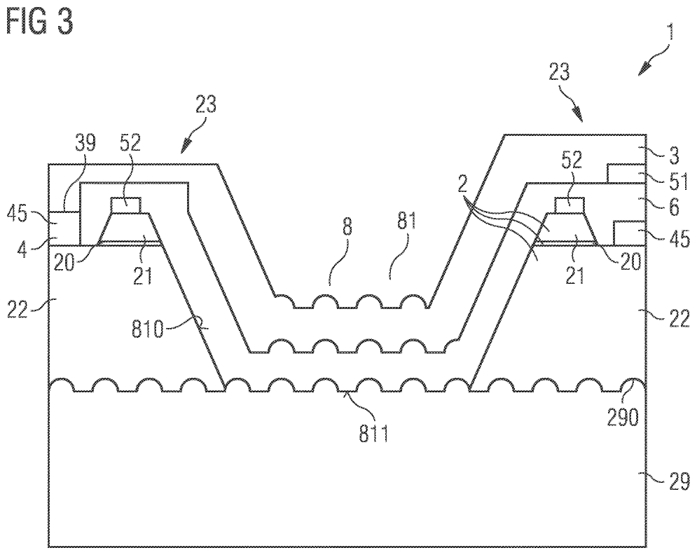

FIG. 3 shows a further embodiment of a radiation-emitting semiconductor chip 1, the figure representing a sectional view along the line CC′ of FIG. 1A.

This embodiment corresponds substantially to the embodiment described in connection with FIGS. 1A to 1C. In contrast thereto, only the first contact layer 3 overlaps with the separating structure 8, configured as a separating trench 81. The first contact layer 3 is passed over the side faces 810 of the separating trench 81 to the neighboring segment 23 and contacts the second contact finger structure 45 there, so that the segments are electrically connected to one another in series.

In a contact region 39, the first contact layer 3 and the second contact layer 4 adjoin one another directly. As seen in the lateral direction, a part of the first semiconductor layer 21 and of the active region 20 is arranged between the contact region 39 and the separating structure 8.

In the region of the separating structure 8, the first contact layer 3 and the second contact layer 4 do not overlap. Only one contact layer is thus passed over the side faces 810 of the separating trench 81.

Neither the first contact layer 3 nor the second contact layer 4 directly adjoins the substrate 29 in the region of the separating trench 81. A bottom surface 811 of the separating trench 81 is fully covered with the insulation layer 6.

No metal layer thus adjoins the substrate 29, in particular the structuring 290 of the substrate. Absorption losses at the interface between the structuring 290 of the substrate 29 and a metal layer may thus be avoided.

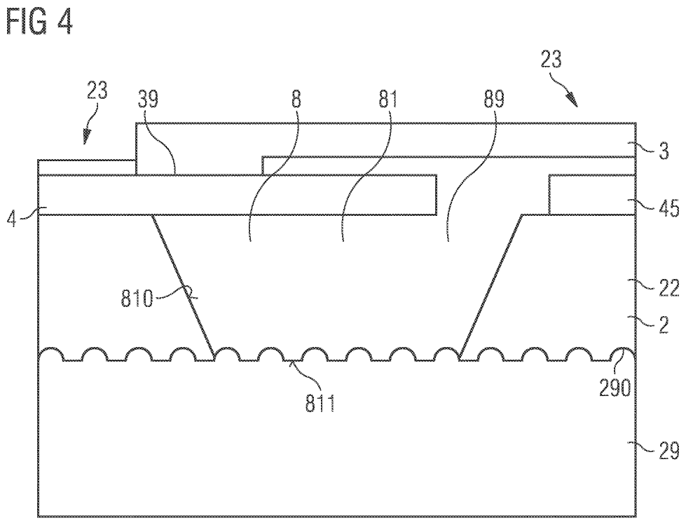

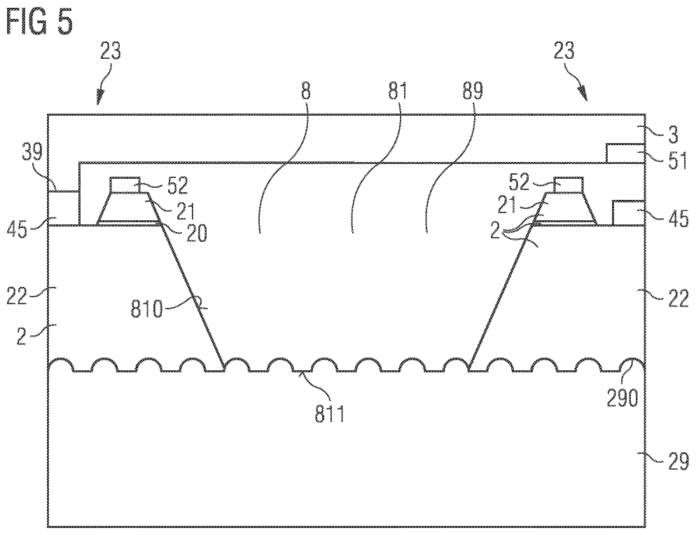

A further embodiment of a radiation-emitting semiconductor chip is shown in FIG. 4, FIG. 4 representing a section along the line CC′ of FIG. 1A.

This embodiment corresponds substantially to the embodiment described in connection with FIG. 1C. In contrast thereto, the separating trench 81 is filled at least partially, in the embodiment shown fully, with an electrically insulating filler material 89. In particular, a dielectric material is suitable for the filler material, for example one of the materials mentioned in connection with the insulation layer. The first contact layer 3 and the second contact layer 4 may thereby be passed in an entirely planar fashion, or in an at least substantially planar fashion, over the separating trench 81. In this way, a constant cross section of the contact layers may be achieved in a straightforward way.

In contrast to the embodiment described, the separating trench 81 need not be filled fully with the filler material 89. It may also be sufficient to fill the separating trench only to at least 30% or to at least 70% or to at least 90% of its vertical extent with an electrically insulating filler material.

A further embodiment of a radiation-emitting semiconductor chip is shown in FIG. 5, FIG. 5 representing a section along the line CC′ of FIG. 1A. This embodiment corresponds substantially to the embodiment described in connection with FIGS. 3.

In contrast thereto, the separating trench 81 is filled with an electrically insulating filler material 89, as described in connection with FIG. 4. In particular, the separating trench may contain only the electrically insulating filler material 89. In this case, no metal layer is thus arranged in the separating trench.

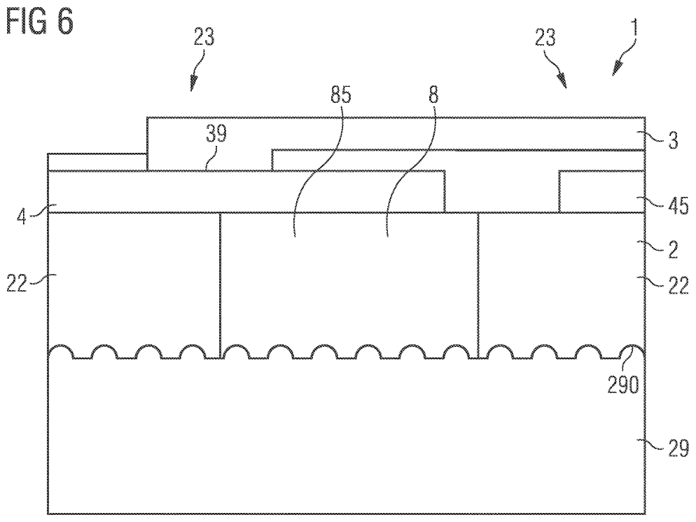

A further embodiment of a radiation-emitting semiconductor chip is shown in FIG. 6, the figure representing a sectional view along the line CC′ of FIG. 1A.

In contrast to the embodiment described in connection with FIGS. 1A to 1C, the separating structure 8 is formed by means of a region 85 of the semiconductor body 2, the electrical conductivity being deliberately reduced locally in comparison with the adjacent material. In particular, the region 85 is electrically insulating. The region may, for example, be produced by ion implantation. The material of the second semiconductor layer 22 is thus not removed in the region of the separating structure 8, merely electrically deactivated. The electrical contacting between the first contact layer 3 and the second contact layer 4 may be carried out as described in connection with FIG. 4. In contrast to FIG. 4, however, no filler material 89 is required in order to configure the first contact layer 3 and the second contact layer 4 in a planar or at least substantially planar fashion.

In the region of the separating structure 8, only the first semiconductor layer 21 and the active region 20 are removed.

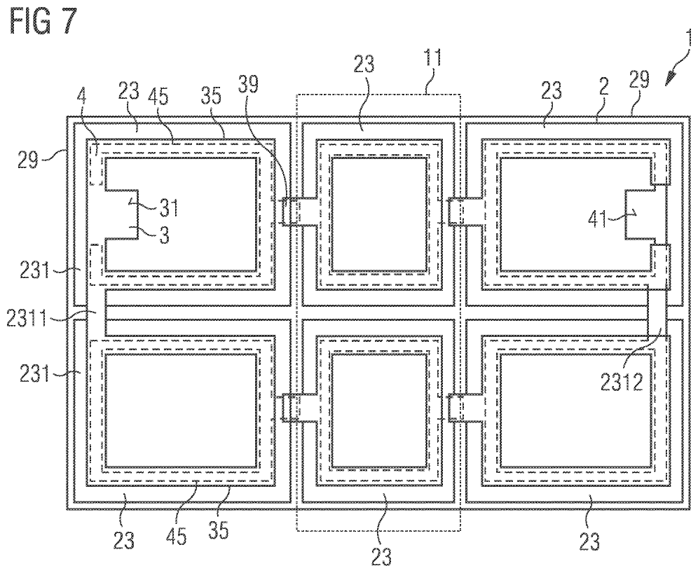

FIG. 7 shows a further embodiment of a radiation-emitting semiconductor chip 1. This embodiment corresponds substantially to the embodiment described in connection with FIGS. 1A to 1C. In contrast thereto, the radiation-emitting semiconductor chip includes two lines 231 of segments 23, the lines 231 being electrically connected to one another in parallel. The segments 23 within a line 231 are electrically connected to one another in series. Overall, all the segments 23 of the semiconductor chip 1 are thus connected to one another in a series-parallel circuit, and are externally electrically accessible via the first contact pad 31 and the second contact pad 41.

Of course, the radiation-emitting semiconductor chip 1 may also include more than two lines 231 and/or more than three segments per line.

The first contact finger structures 35 of neighboring lines are electrically connected to one another by means of a first line connector 2311. Correspondingly, the second contact finger structures 45 are electrically conductively connected to a second line connector 2312 of the second contact layer 4. By a parallel connection of lines 231, the operating current through the optoelectronic semiconductor chip 1 may be increased overall without the current per segment being increased.

Of course, a parallel connection of segments 23, or of lines of segments, may also be suitable for the embodiments described in connection with FIGS. 2 to 6.

The description with the aid of the embodiments does not restrict the invention to these embodiments; rather, the invention includes any new feature and any combination of features. This includes in particular any combination of features in the patent claims, even if this feature or this combination is not itself explicitly indicated in the patent claims or the embodiments.

### LIST OF REFERENCES

1 radiation-emitting semiconductor chip
11 unit cell
2 semiconductor body
20 active region
21 first semiconductor layer
22 second semiconductor layer
23 segment
231 line
2311 first line connector
2312 second line connector
25 recess
250 side face
28 radiation exit surface
29 substrate
290 structuring
3 first contact layer
31 first contact pad
35 first contact finger structure
37 subregion of the first contact finger structure
39 contact region
4 second contact layer
41 second contact pad
45 second contact finger structure
51 current distribution layer
52 connecting layer
6 insulation layer
60 opening
8 separating structure
81 separating trench
810 side face
811 bottom surface
85 region
89 filler material

1. A radiation-emitting semiconductor chip, comprising
a semiconductor body having a first semiconductor layer, a second semiconductor layer, and an active region arranged between the first semiconductor layer and the second semiconductor layer and is configured to generate radiation;
wherein the active region is subdivided into a multiplicity of segments in a plan view of the semiconductor chip, a separating structure respectively being formed in the semiconductor body between neighboring segments;
the multiplicity of segments are electrically connected to one another in series and/or parallel; and
at least one segment is assigned a first contact layer having a first contact finger structure for electrical contacting of the first semiconductor layer and a second contact layer having a second contact finger structure for electrical contacting of the second semiconductor layer, the first contact finger structure and the second contact finger structure overlapping in places in a plan view of the semiconductor chip, and wherein there is a direct electrical contact between the first contact layer and the second contact layer in places.

2. The radiation-emitting semiconductor chip as claimed in claim 1,
wherein the first contact layer and the second contact layer overlap with the separating structure at least between two segments in a plan view of the semiconductor chip.

3. The radiation-emitting semiconductor chip as claimed in claim 1,
wherein either only the first contact layer or only the second contact layer overlaps with the separating structure at least between two segments in a plan view of the semiconductor chip.

4. The radiation-emitting semiconductor chip as claimed in claim 1,
wherein the separating structure is formed by a separating trench extending fully through the semiconductor body in the vertical direction.

5. The radiation-emitting semiconductor chip as claimed in claim 4,
wherein the separating trench is filled to at least 30% of its vertical extent with an electrically insulating filler material.

6. The radiation-emitting semiconductor chip as claimed in claim 4,
wherein a side face of the separating trench is inclined at an angle of at most 70° with respect to a main extent plane of the active region.

7. The radiation-emitting semiconductor chip as claimed in claim 1,
wherein the separating structure is formed by a region of the semiconductor body in which an electrical conductivity is reduced in comparison with a laterally adjacent material of the semiconductor body.

8. The radiation-emitting semiconductor chip as claimed in claim 1,
wherein the semiconductor chip comprises a current distribution layer and a connecting layer, the current distribution layer being electrically conductively connected to the first semiconductor layer by the connecting layer.

9. The radiation-emitting semiconductor chip as claimed in claim 8,
wherein the first contact finger structure is electrically conductively connected to the current distribution layer, and wherein the first contact finger comprises at least one subregion where the current distribution layer is not directly adjacent.

10. The radiation-emitting semiconductor chip as claimed in claim 8,
wherein the semiconductor chip comprises an insulation layer having a dielectric material, the insulation layer being arranged between the connecting layer and the current distribution layer in places.

11. The radiation-emitting semiconductor chip as claimed in claim 10,
wherein the insulation layer covers the connecting layer to at least 30% of the area of the connecting layer.

12. The radiation-emitting semiconductor chip as claimed in claim 10,
wherein the insulation layer comprises at least one opening, in which the connecting layer and the current distribution layer adjoin one another.

13. The radiation-emitting semiconductor chip as claimed in claim 10,
wherein the insulation layer is configured as a filter layer, which transmits radiation incident within a first angle range and reflects radiation incident within a second angle range.

14. The radiation-emitting semiconductor chip as claimed in claim 1,
wherein at least 50% of the total area of the second contact finger structure overlaps with the first contact finger structure.

15. The radiation-emitting semiconductor chip as claimed in claim 1,
wherein the semiconductor body comprises at least one recess, which extends from the radiation exit surface through the active region, and wherein the second contact layer is electrically conductively connected to the semiconductor body in the recess.
